(19) United States
(12) Patent Application Publication
(10) Pub. No.: US 2026/0255882 A1
(43) Pub. Date: Aug. 27, 2026

(54) METHOD OF MANUFACTURING MAGNETIC MEMORY DEVICE

(71) Applicant: SK hynix Inc., Gyeonggi-do (KR)

(72) Inventors: Jung Hyeok KWAK, Gyeonggi-do (KR); Tae Yup KIM, Gyeonggi-do (KR); Ku Youl JUNG, Gyeonggi-do (KR); Jin Won JUNG, Gyeonggi-do (KR); Young Ki CHAI, Gyeonggi-do (KR)

(21) Appl. No.: 19/319,662

(22) Filed: Sep. 4, 2025

(30) Foreign Application Priority Data
Feb. 21, 2025 (KR) 10-2025-0022785

(51) Int. Cl. H10N 50/01; H10B 61/00; H10N 50/10

(52) U.S. Cl. CPC H10N 50/01; H10B 61/10; H10N 50/10

(57) ABSTRACT

In a method of manufacturing a magnetic memory device, a temporary shift cancel layer including X metal atoms and Y metal atoms as free atoms may be formed. A magnetic tunnel junction layer may be formed on the temporary shift cancel layer. The magnetic tunnel junction layer and the temporary shift cancel layer may be etched to form a magnetic tunnel junction pattern and a temporary shift cancel pattern. The Y metal atoms redeposited between the magnetic tunnel junction pattern and the temporary shift cancel pattern may be oxidized to form metal oxide. The Y metal atoms of the temporary shift cancel pattern may be substituted with Z metal atoms to form a shift cancel pattern. The Y metal atoms may have higher oxidizing than the Z metal atoms. The Z metal atoms may have a higher reduction potential than the Y metal atoms.

### CROSS-REFERENCES TO RELATED APPLICATION

The present application claims priority under 35 U.S.C. § 119(a) to Korean application number 10-2025-0022785, filed on Feb. 21, 2025, which is incorporated herein by reference in its entirety.

### BACKGROUND

### 1. Technical Field

Various embodiments of the present disclosure relate generally to a method of manufacturing a magnetic memory device.

### 2. Related Art

A magnetic memory device may include a plurality of word lines, a plurality of bit lines and a plurality of magnetic memory cells.

The plurality of word lines and the plurality of bit lines may be arranged to intersect each other. The plurality of magnetic memory cells may be located at intersections of the plurality of word lines and the plurality of bit lines, respectively. Each of the plurality of magnetic memory cells may include a magnetic tunnel junction pattern including a free layer, a tunnel barrier layer and a fixed layer.

However, a magnetic field imbalance may be generated due to a thickness difference between the free layer and the fixed layer, and a component difference between the free layer and the fixed layer. To reduce the magnetic field imbalance, a shift cancel layer (SCL) may be formed at a position adjacent to the fixed layer or the free layer.

### SUMMARY

According to embodiments of the present disclosure, there is provided a method of manufacturing a magnetic memory device. In the method of manufacturing the magnetic memory device, a temporary shift cancel layer including X metal atoms and Y metal atoms as free atoms may be formed. A magnetic tunnel junction layer may be formed on the temporary shift cancel layer. The magnetic tunnel junction layer and the temporary shift cancel layer may be etched to form a magnetic tunnel junction pattern and a temporary shift cancel pattern. The Y metal atoms redeposited between the magnetic tunnel junction pattern and the temporary shift cancel pattern may be oxidized to form metal oxide. The Y metal atoms of the temporary shift cancel pattern may be substituted with Z metal atoms to form a shift cancel pattern. The Y metal atoms may have higher oxidizing than the Z metal atoms. The Z metal atoms may have a higher reduction potential than the Y metal atoms.

According to embodiments of the present disclosure, there is provided a method of manufacturing a magnetic memory device. In the method of manufacturing the magnetic memory device, a switching structure may be formed on a semiconductor substrate. A temporary shift cancel layer including X metal atoms, which may include at least one of Co and Fe, and Y metal atoms, which may include at least one of Pd and Ni, may be formed on the switching structure. A first magnetic layer, a tunnel barrier layer and a second magnetic layer may be stacked on the temporary shift cancel layer to form a magnetic tunnel junction layer. The magnetic tunnel junction layer and the temporary shift cancel layer may be etched at least once using an ion beam to form a temporary shift cancel pattern and a magnetic tunnel junction pattern on the switching structure. A portion between the magnetic tunnel junction patterns and a sidewall portion of the magnetic tunnel junction pattern may be oxidized. The Y metal atoms may be substituted with Pt metal atoms through a sidewall of the temporary shift cancel pattern to form a shift cancel pattern.

According to embodiments of the present disclosure, the shift cancel pattern may be formed by immersing the temporary shift cancel pattern in a solution including Pt metal atoms. The solution containing the Pt metal atoms may include H2PtCl6, PtCl2, PtCl4, or PtF4.

According to embodiments of the present disclosure, there is provided a magnetic memory device. The magnetic memory device may include a first signal line, a switching structure, a shift cancel pattern, a magnetic tunnel junction pattern, and a second signal line. The switching structure may be electrically coupled to the first signal line. The shift cancel pattern may be connected with the switching structure. The shift cancel pattern may include X metal atoms, Y metal atoms and Z metal atoms. The magnetic tunnel junction pattern may be formed on the shift cancel pattern. The second signal line may be connected with the magnetic tunnel junction pattern. The Y metal atoms may have higher oxidizing than the Z metal atoms. The Z metal atoms may have a higher reduction potential than the Y metal atoms. A concentration of the Z metal atoms in the shift cancel pattern may be gradually increased from a central region to an edge region in the shift cancel pattern. A concentration of the Y metal atoms in the shift cancel pattern may be gradually decreased from the central region to the edge region in the shift cancel pattern.

According to embodiments of the present disclosure, the shift cancel pattern may include a first atomic layer and a second atomic layer stacked alternately at least one. The first atomic layer may include the Y metal atoms and the Z metal atoms. The second atomic layer may include the X metal atoms.

According to embodiments of the present disclosure, a concentration of the Z atoms in the first atomic layer may be gradually increased from the central region to the edge region. A concentration of the Y metal atoms in the first atomic layer may be gradually decreased from the center region to the edge region.

According to embodiments of the present disclosure, the X metal atoms may include at least one metal atom selected from Co and Fe. The Y metal atoms may include at least one metal atom selected from Pd and Ni. The Z metal atoms may include a Pt metal atom.

According to embodiments of the present disclosure, the magnetic memory device may further include an insulating interlayer formed between adjacent laminates of the shift cancel pattern and the magnetic tunnel junction pattern. The insulating interlayer may partially include Y metal oxide.

According to embodiments of the present disclosure, during the ion beam etching process of the temporary magnetic layer, which may include the X metal atoms and the strongly oxidizing Y metal atoms as free electrons and the magnetic tunnel junction layer, the Y metal atoms dissociated from the temporary shift cancel pattern may be converted into metal oxides, thereby preventing bridge and shunt defects. Furthermore, the Y metal atoms remaining in the temporary shift cancel layer may be substituted with the Z metal atoms, such as the Pt atoms, which may improve magnetic properties, thereby enhancing vertical magnetic anisotropy characteristics of the shift cancel pattern. As a result, the electrical characteristics of the magnetic memory device may be improved.

### BRIEF DESCRIPTION OF THE DRAWINGS

The above and other embodiments, features and advantages of the subject matter of the present disclosure will be more easily understood from the following detailed description taken in conjunction with the accompanying drawings, in which:

FIG. 1 is a perspective view illustrating a resistive memory device in accordance with embodiments of the present disclosure;

FIG. 2 is a concept view illustrating a magnetic memory cell in accordance with embodiments of the present disclosure;

FIGS. 3 to 8 are cross-sectional views illustrating a method of manufacturing a magnetic memory device in accordance with embodiments of the present disclosure; and

FIG. 9 is an enlarged cross-sectional view illustrating a shift cancel pattern in FIG. 8.

### DETAILED DESCRIPTION

The advantages and features of the embodiments of the present disclosure, and methods of achieving them, will become apparent upon reference to the embodiments described in detail with reference to the accompanying drawings. However, the invention is not limited to the embodiments disclosed herein, but can be embodied in many different forms, and these embodiments are provided merely to make the present disclosure complete and to give a complete picture of the scope of the present disclosure to one of ordinary skill in the art. The dimensions and relative sizes of the layers and regions in the drawings may be exaggerated for clarity of description. Throughout the specification, like reference numerals refer to like components.

According to embodiments of the present disclosure, at least one atom of metal atoms in a shift cancel layer may be replaced with metal atoms (hereinafter, replaced metal atoms) having an excellent oxidizing property. When the shift cancel layer and a magnetic tunnel junction layer may be etched to form a shift cancel pattern and a vertical magnetic tunnel junction pattern, the replaced metal atoms of the shift cancel pattern may be redeposited between the shift cancel pattern and the magnetic tunnel junction pattern. Redeposited metal atoms may be oxidized to operate as an insulating interlayer. After the shift cancel pattern is formed, the replaced metal atoms may be substituted by other metal atoms to compensate for vertical magnetic anisotropy characteristic. Accordingly, electrical characteristics between the magnetic tunnel junction pattern and the vertical magnetic tunnel junction pattern of the shift cancel pattern may be simultaneously improved.

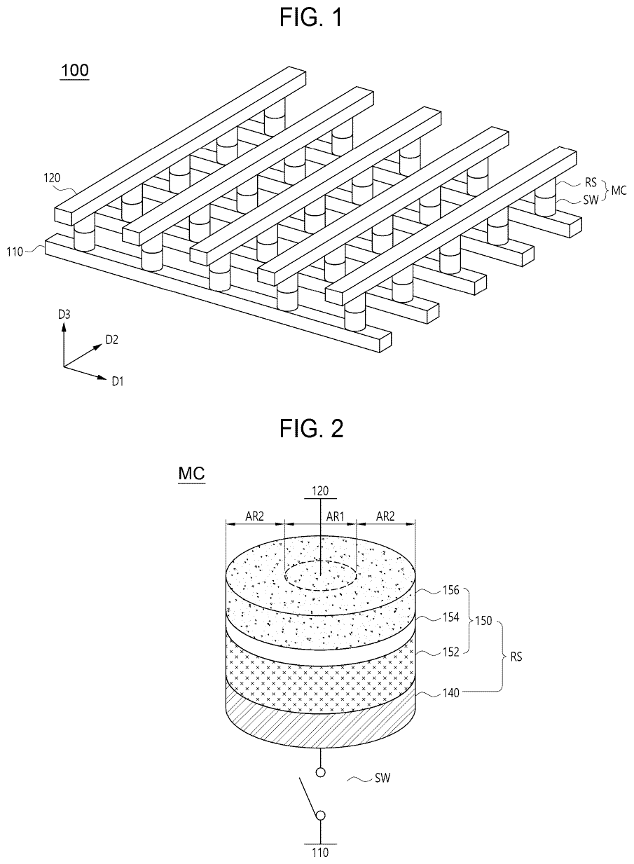

FIG. 1 is a perspective view illustrating a magnetic memory device in accordance with embodiments of the present disclosure.

Referring to FIG. 1, a magnetic memory device 100 may include a plurality of first signal lines 110, a plurality of second signal lines 120 and a plurality of magnetic memory cells MC.

The plurality of first signal lines 110 may be arranged in parallel along a first direction D1. For example, the plurality of first signal lines 110 may be a plurality of word lines or a plurality of bit lines. For example, the plurality of first signal lines 110 may include at least one of a metal, a metal nitride, and a stacked layer of the metal and the metal nitride.

The plurality of second signal lines 120 may be disposed over the plurality of first signal lines 110. The plurality of second signal lines 120 may not contact the plurality of first signal lines 110. The plurality of second signal lines 120 may extend parallel along a second direction D2 intersected with the first direction D1. Hence, the plurality of the first and second signal lines may be arranged in a grid-like structure where they intersect, and their connection is controlled through memory cells MC. For example, the plurality of second signal lines 120 may be the plurality of bit lines or the plurality of word lines. For example, the plurality of second signal lines 120 may also include at least one of a metal, a metal nitride, and a stacked layer of the metal and the metal nitride. For example, the plurality of first signal lines 110 may include the plurality of word lines, and the plurality of second signal lines 120 may include the plurality of bit lines.

For example, the metal making up the first signal line 110 or the second signal line 120 may include at least one of platinum (Pt), tungsten (W), aluminum (Al), copper (Cu), and tantalum (Ta).

For example, the first signal line 110 or the second signal line 120 may include a metal nitride such as at least one of titanium nitride (TiN), tantalum nitride (TaN), tungsten nitride (WN) and aluminum nitride (AlN).

Further, the first signal line 110 and the second signal line 120 may include the same material or different materials. The first signal line 110 and the second signal line 120 may include a single conductive layer or multiple conductive layers. Using multiple conductive layers may optimize the electrical performance of the first and second signal lines.

The plurality of magnetic memory cells MC may be located at intersections between the plurality of first signal lines 110 and the plurality of second signal lines 120, respectively. Accordingly, the magnetic memory device may have a cross-point array structure with the memory cells MC arranged at the intersections of the first signal lines 110 and the second signal lines 120.

According to some embodiments, the plurality of magnetic memory cells MC may include a switching structure SW and a resistive structure RS. The switching structure SW may access the resistive structure RS.

The switching structure SW may reduce a disturbance between adjacent memory cell(s) MC. For example, the switching structure SW may prevent a malfunction of the magnetic memory cell MC by a leakage current between the first and second signal lines 110 and 120.

The resistive structure RS may selectively store data under the control of the switching structure SW.

FIG. 2 is a concept view illustrating a resistive structure of a magnetic memory cell in accordance with embodiments of the present disclosure.

Referring to FIGS. 1 to 2, the magnetic memory cell MC may include the switching structure SW and the resistive structure RS described above.

The switching structure SW may electrically connect the first signal line 110 with the resistive structure RS. The resistive structure RS may be connected between the switching structure RS and the second signal line 120.

For example, the resistive structure RS may include a shift cancel pattern 140 and a magnetic tunnel junction pattern 150.

The shift cancel pattern 140 may be positioned between the switching structure SW and the magnetic tunnel junction pattern 150. The shift cancel pattern 140 may be provided to compensate for a magnetic field imbalance of the magnetic tunnel junction pattern 150. The shift cancel pattern 140 may include a material having readily changed magnetism. The shift cancel pattern 140 may include, for example, a plurality of metal atoms. For example, the shift cancel pattern 140 may include X metal atoms and Z metal atoms. According to some embodiments, the shift cancel pattern 140 may include the X metal atoms, the Z metal atoms and Y metal atoms.

For example, the X metal atoms may be a ferromagnetic material providing a strong magnetic moment. When metallically bonded with the Z atoms and the Y metal atoms, the X metal atoms may be operated as metal cations. For example, the X metal atoms may include at least one of Co and Fe.

The Z metal atoms may provide strong spin-orbital coupling with the X metal atoms. When the Z metal atoms are bonded to the X metal atoms, the Z metal atoms may operate as a free electron. The Z metal atoms may help with the alignment of magnetic moments of the X metal atoms in a vertical direction (for example, third direction: D3) to improve vertical magnetic anisotropy of the shift cancel pattern 140. Further, the Z metal atoms may form a particular crystal structure, such as an L1_0 structure, with the X metal atoms. The Z metal atoms may be combined with the X metal atoms to improve structural stability and magnetic properties of the shift cancel pattern 140. For example, the Z metal atoms may include Pt metal atoms.

The X-Y metal atoms bonds may provide a spin-orbit coupling lower than the X-Z metal atoms bonds. The Y metal atoms may have a higher outermost electron number than the Z metal atoms to have higher oxidizing than the Z metal atoms. The Y metal atoms may also operate as free electrons. Further, the Z metal atoms may have a higher reduction potential than the Y metal atoms. For example, the Y metal atoms may include at least one of palladium (Pd) and nickel (Ni).

According to some embodiments, a concentration of the Z metal atoms in the shift cancel pattern 140 may be gradually increased from the central region AR1 toward an edge region AR2 in the shift cancel pattern 140.

When the shift cancel pattern 140 includes the Y metal atoms, the Y metal atoms may have a higher concentration in the central region AR1 than in the edge region AR2. The concentration of the Y metal atoms in the shift cancel pattern 140 may be lower than a concentration of the Z metal atoms. In some cases, the shift cancel pattern 140 may include very few Y metal atoms.

The magnetic tunnel junction pattern 150 may include a first magnetic pattern 152, a tunnel barrier pattern 154 and a second magnetic pattern 156.

For example, the first magnetic pattern 152 may include a fixed layer. The first magnetic pattern 152 may be formed over the shift cancel pattern 140. The first magnetic pattern 152 may include a ferromagnetic material providing a fixed magnetization direction.

The tunnel barrier pattern 154 may be positioned between the first magnetic pattern 152 and the second magnetic pattern 156. The tunnel barrier pattern 154 may include a material for electrically insulating the first magnetic pattern 152 from the second magnetic pattern 156.

For example, the second magnetic pattern 156 may include a free layer, i.e., a layer whose magnetization can change freely in response to external magnetic fields or electrical currents. The second magnetic pattern 156 may include a ferromagnetic material, wherein the magnetization direction thereof is configurable based on an applied voltage or current transmitted via the second signal line 120. In certain embodiments, the magnetization direction of the second magnetic pattern 156 may be altered through spin transfer torque induced by the voltage or current applied via the second signal line 120. Depending on a difference between the magnetization direction of the second magnetic pattern 156 and the magnetization direction of the first magnetic pattern 152, a resistance of the magnetic tunnel junction pattern 150 may be changed, thereby performing a memory operation of the magnetic memory cell MC.

An effect of stray magnetic fields generated in the first magnetic pattern 152 may be offset or reduced by the shift cancel pattern 140. That is, when a ferromagnetic material such as the first magnetic pattern 152 generates a magnetic field, unintended or stray magnetic influences can affect neighboring components, potentially disrupting memory operations. The shift cancel pattern is engineered to counteract or reduce these stray fields, ensuring stable magnetic conditions for memory cells. In addition, any deflected magnetic field generated in the second magnetic pattern 156 may also be offset or reduced by the shift cancel pattern 140. For example, the shift cancel pattern 140 may provide a magnetization direction opposite to the first magnetic pattern 152. By providing a magnetization direction opposite to that of the first magnetic pattern 152, it effectively neutralizes stray magnetic fields that could interfere with the stability and performance of the system. The shift cancel pattern 140 may be designed with a magnetization orientation that directly opposes the first magnetic pattern 152. This counteracts the influence of stray fields, preventing unintended disruptions in adjacent memory cells.

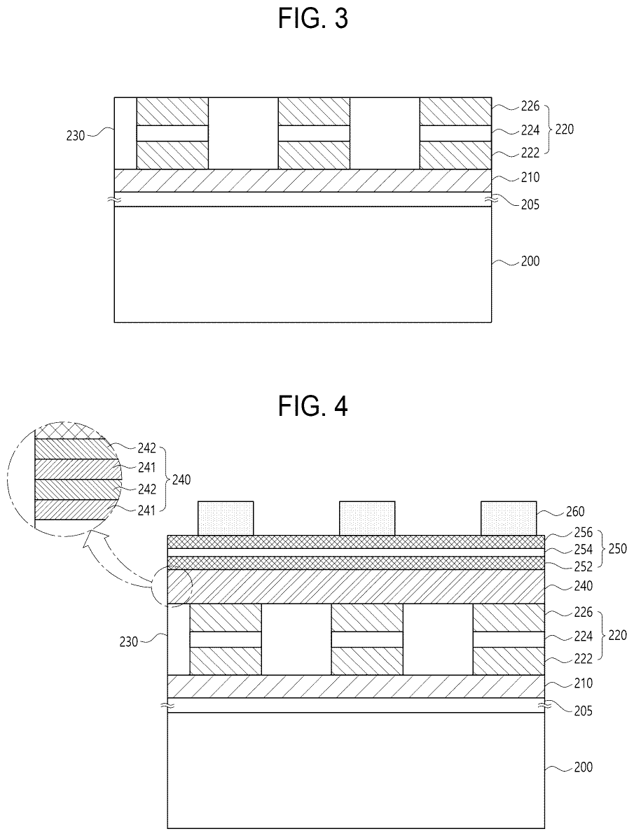

FIGS. 3 to 8 are cross-sectional views illustrating a method of manufacturing a magnetic memory device in accordance with embodiments of the present disclosure.

Referring to FIG. 3, a first conductive layer (not shown) may be formed on a substrate 200 on which an insulating interlayer 205 may be formed. The substrate 200 may be a semiconductor substrate including silicon, SOI (Silicon on Insulator), silicon germanium (SiGe), germanium (Ge), gallium arsenide (GaAs), and the like. The insulating interlayer 205 may include at least one insulation material. Further, various circuit patterns (not shown) may be formed in the insulating interlayer 205.

The first conductive layer may be patterned using a mask pattern (not shown) for the first signal line to form a first signal line 210 on the substrate 200. For example, the first signal line 210 may be one selected from a word line and a bit line.

A second conductive layer, a selector layer and a third conductive layer may be sequentially formed on the first signal line 210 and may be patterned to form switching structure 220 including lower electrode 222, selector 224 and intermediate electrode 226 as shown in FIG. 3. According to some embodiments, the second conductive layer may be electrically connected to the first signal line 210. The second conductive layer and the third conductive layer may include at least one of a metal material, such as titanium (Ti) and tantalum (Ta) and a metal nitride material, such as titanium nitride (TiN) and tantalum nitride (TaN). The selector layer may control a flow of a current depending on a magnitude of a voltage or a current applied to the second conductive layer and the third conductive layer. For example, the selector layer may be an insulation layer including conductive impurities.

A first insulating interlayer 230 may be formed over the first signal line 210 in which the switching structure 220 may be formed. The first insulating interlayer 230 may be formed with a thickness such that a space between the switching structures 220 may be buried, meaning that it fills the gaps or space between the switching structures completely. The first insulating interlayer 230 may be planarized to expose an upper surface of the switching structures 220.

Referring to FIG. 4, a temporary shift cancel layer 240 may be formed on the switching structure 220 and the first insulating interlayer 230. The temporary shift cancel layer 240 may include a metallic compound having magnetic properties. According to various embodiments, the temporary shift cancel layer 240 may be a metal compound including XmYn (X and Y are metal atoms, m and n are natural numbers).

The X metal atoms may be a ferromagnetic material that provides a strong magnetic moment. When the X metal atoms are metallically bonded to the Y metal atoms, the X metal atoms may be operated as metal cations. For example, the X metal atoms may include at least one of cobalt (Co) and iron (Fe).

The Y metal atoms may provide relatively low spin-orbit coupling with the X metal atoms. The Y metal atoms may have a relatively high number of outermost electrons, which may provide excellent oxidizing. The Y metal atoms may act as a free electron in the XmYn compound. For example, the Y metal atoms may include at least one of palladium (Pd) and nickel (Ni).

For example, the temporary shift cancel layer 240 may include interatomic bonds between the X metal atoms and Y metal atoms (hereinafter, referred to as X-Y metal bonds) and interatomic bonds between Y metal atoms (i.e., Y metal atoms and Y metal atoms bonds, hereinafter, referred to as Y-Y metal bonds). A bonding force of the bond between the Y metal atoms and oxygen atoms (Y-O bond) may be stronger than the X-X metal bond, the X-Y metal bond and the Y-Y metal bond.

According to some embodiments, a first atomic layer 241 may be formed over the switching structure 220 and the first insulating interlayer 230 as shown in FIG. 4. A second atomic layer 242 may be formed on the first atomic layer 241 The process of forming the first atomic layer 241 and the process of forming the second atomic layer 242 may be repeated at least once, thereby forming the temporary shift cancel layer 240. The first atomic layer 241 may include the Y metal atomic layer. The second atomic layer 242 may include the X metal atomic layer. However, without limitation, the first atomic layer 241 may include the X metal atomic layer and the second atomic layer 242 may include the Y metal atomic layer. For example, the first and second atomic layers, 241 and 242, may be formed using, for example, an atomic layer deposition (ALD) process or a plasma-enhanced atomic layer deposition (PEALD) process.

A magnetic tunnel junction layer 250 may be formed on the temporary shift cancel layer 240. For example, forming the magnetic tunnel junction layer 250 may include forming a first magnetic layer 252, forming a tunnel barrier layer 254 on the first magnetic layer 252, and forming a second magnetic layer 256 on the tunnel barrier layer 254.

First, the first magnetic layer 252 may be formed to contact the temporary shift cancel layer 240. The first magnetic layer 252 may be a fixed layer providing a fixed magnetization direction. The first magnetic layer 252 may include at least one of Co, Fe and Pt. For example, the first magnetic layer 252 may include at least one of CoPt, CoFePt and FePt.

The tunnel barrier layer 254 may be formed of a material capable of insulating the first magnetic layer 252 and the second magnetic layer 256, but capable of causing tunneling between the first magnetic layer 252 and the second magnetic layer 256. For example, the tunnel barrier layer 254 may include magnesium oxide (MgOx), aluminum oxide (AlOx), or titanium oxide (TiOx).

The second magnetic layer 256 may be a free layer whose magnetization direction may be changed by an external stimulus. In response to the change in the magnetization direction of the second magnetic layer 256, a resistance of the magnetic tunnel junction layer 250 may be changed. According to the change in resistance of the magnetic tunnel junction layer 250, the magnetic tunnel junction layer 250 may exhibit different data states. Consequently, the magnetization direction of the second magnetic layer 256 may determine the data state of the magnetic tunnel junction layer 250. Therefore, the second magnetic layer 256 may be a substantial storage layer. The second magnetic layer 256 may include a ferromagnetic material having a single layer structure or a multi-layer structure. For example, the second magnetic layer 256 may include CoFeB. According to other embodiments, the second magnetic layer 256 may include at least one of a vertical magnetic material (e.g., CoFeTb, CoFeGd, CoFeDy), a vertical magnetic material having the L1_0 structure, CoPt having the hexagonal close packed lattice structure, and the vertical magnetic structure.

According to various embodiments, the temporary shift cancel layer 240 may be formed to have a greater thickness than the first and second magnetic layers 252 and 256 to be able to resolve a magnetic field imbalance of the first and second magnetic layers 252 and 256.

A hard mask pattern 260 may be formed on the magnetic tunnel junction layer 250. For example, the hard mask pattern 260 may be formed to overlap the switching structure 220. According to some embodiments, the hard mask pattern 260 may be formed of a material having an etch selectivity with each of the magnetic tunnel junction layer 250 and the temporary shift cancel layer 240.

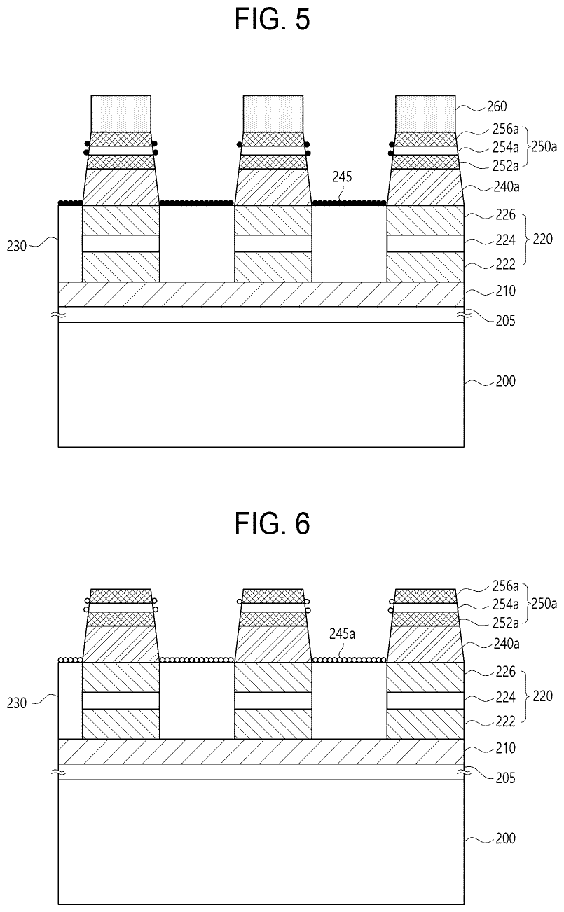

Referring to FIG. 5, the second magnetic layer 256, tunnel barrier layer 254, first magnetic layer 252 and the temporary shift cancel layer 240 may be etched using the hard mask pattern 260 to form a magnetic tunnel junction pattern 250a, which may include a first magnetic pattern 252a, a tunnel barrier pattern 254a and a second magnetic pattern 256, and a temporary shift cancel pattern 240a.

According to some embodiments, the second magnetic layer 256, the tunnel barrier layer 254, the first magnetic layer 252 and the temporary shift cancel layer 240 may be patterned by a plurality of ion beam etchings. The plurality of ion beam etchings may physically and chemically remove the second magnetic layer 256, the tunnel barrier layer 254, the first magnetic layer 252 and the temporary shift cancel layer 240 by irradiating an ion beam in an oblique direction not perpendicular to the surface of the substrate 200 at least once onto the etching object 256, 254, 252 and 240. The diagonal direction may include a direction that forms about ±15° to about ±45° with respect to a surface of the substrate 200.

However, since the temporary shift cancel layer 240 may be formed to have a greater thickness than the first and second magnetic layers 252 and 254, Y metal atoms corresponding to free electrons in the temporary shift cancel layer 240 may be redeposited onto the surface of the first insulating interlayer between the magnetic tunnel junction patterns and the sidewalls of the magnetic tunnel junction patterns 250a by the ion beam etching. Because the Y metal atoms in the temporary shift cancel layer 240 may also be conductive, the redeposited metal material 245 may cause bridging or shunting between the magnetic tunnel junction patterns 250a.

As shown in FIG. 6, after removing the hard mask layer 260, the redeposited metal material 245 may be oxidized to form metal oxide 245a. The Y metal atoms of the redeposited metal material 245 may have a relatively high oxidizing (high tendency for oxidation), as previously described. Thus, the Y metal atoms may be readily changed into the metal oxide 245a. Accordingly, the metal oxide 245a may include Y-O bonds, which may be stronger than X-Y metal bonds and Y-Y metal bonds. The oxidation of the redeposited metal material 245 may be carried out by an oxidation process involving an injection of an oxygen-containing gas, or by a natural oxidation process.

According to various embodiments, prior to forming the metal oxide 245a, a cleaning process may be performed to remove any damage and dangling bonds that may have been caused to the surfaces of the temporary shift cancel pattern 240a, the first magnetic pattern 252a and the second magnetic pattern 256a by the ion beam etching.

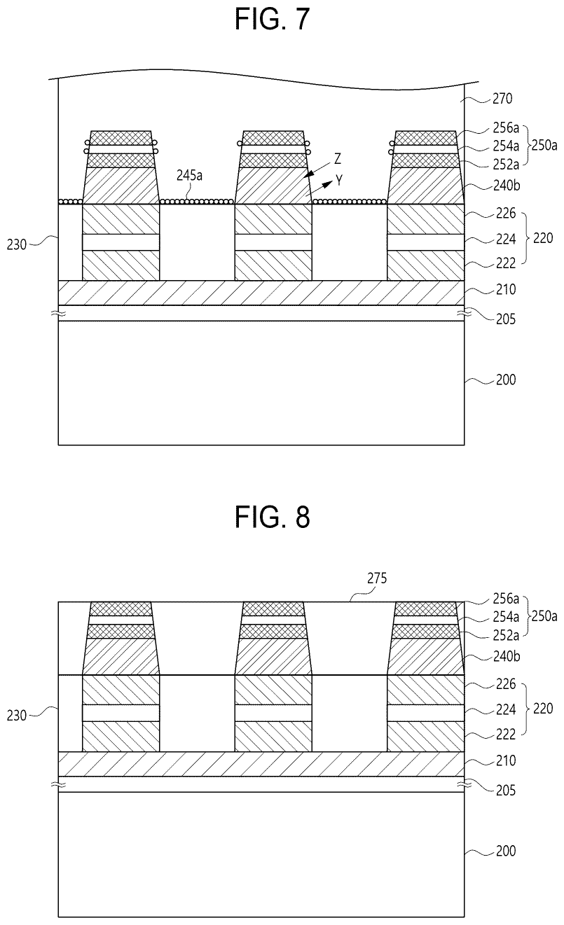

Referring to FIG. 7, the substrate 200 may be immersed in a solution 270 including Z metal atoms. The Z metal atoms have a relatively higher reduction potential than the Y metal atoms. Further, the Z metal atoms may be bonded to the X metal atoms, such that magnetic moments of the X metal atoms may be aligned in a vertical direction. Accordingly, as the X-Z bonding may be increased, the vertical magnetic anisotropy characteristic of the temporary shift cancel pattern 240b may be improved. This, as the resulting substrate 200 including the temporary shift cancel pattern 240b may be immersed in the Z metal atoms containing solution 270, the Y metal atoms (e.g., X-Y metal bonded Y metal atoms) contained in the temporary shift cancel pattern 240a may be substituted, i.e., ionically exchanged, with the Z metal atoms. The Z metal atoms may penetrate through the sidewalls of the temporary magnetic pattern 240b to be substituted with the Y metal atoms. As a result, an edge region adjacent to the sidewalls of the temporary magnetic pattern 240b may become accessible to the Z metal atoms.

On the other hand, since the Y-O bond energy may be higher than the X-Y dissociation energy or the reduction potential of the Z metal atoms, even when the resultant of the substrate 200 may be immersed in the solution 270 containing the Z metal atoms, the Y-O bonds including the metal oxide 245a may remain intact.

According to some embodiments, the Z metal atoms may be Pt atoms, and the Z metal atoms-containing solution 270 may include, for example, H₂PtCl₆, PtCl₂, PtCl₄, or PtF₄. A time of immersion of the resulting substrate 200 in the Z metal atoms containing solution 270, and a concentration of Z metal atoms in the Z metal atoms containing solution 270 may be determined by considering a thickness and a width of the temporary shift cancel pattern 240a.

The metal oxide 245a may remain in the form of an insulation layer between adjacent magnetic tunnel junction patterns 250a because the metal oxide 245a may retain the Y-O bonds, even after undergoing the immersion process.

Referring to FIG. 8, Z metal atoms may be withdrawn from the resulting substrate 200 to form a shift cancel pattern 240b including the Z metal atoms. The shift cancel pattern 240b may include more Z metal atoms (i.e., a higher concentration of Z metal atoms) than Y metal atoms, as the Y metal atoms in the temporary shift cancel pattern 240a may be replaced by Z metal atoms. As a result, the shift cancel pattern 240b may include a greater amount of X-Z bonds than X-Y bonds, leading to improved enhanced magnetic moment and vertical magnetic anisotropy properties than the temporary magnetic pattern 240a, which predominantly includes X-Y bonds.

According to some embodiments, all of the Y metal atoms in the temporary shift cancel pattern 240a may be replaced with the Z metal atoms, or some Y metal atoms may be retained in the central region.

Thereafter, the substrate 200 on which the shift cancel pattern 240b has been formed may be subjected to a further cleaning process and a drying process.

Next, a second insulating interlayer 275 may be formed between the shift cancel pattern 240b and the magnetic tunnel junction pattern 250a to insulate between the adjacent magnetic tunnel junction patterns 250a. In this case, the metal oxide 245a may be included in the second insulating interlayer 275 as a part of the insulating material.

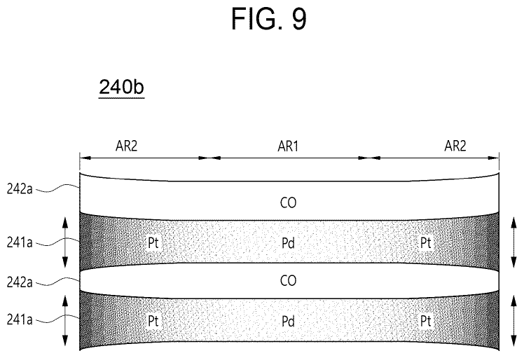

FIG. 9 is an enlarged cross-sectional view illustrating the shift cancel pattern of FIG. 8. For example, the shift cancel pattern 240b of FIG. 9 may be formed by a temporary shift cancel pattern including CoPd material.

Referring to FIG. 9, the shift cancel pattern 240b may include, for example, Co, Pt, and Pd atoms. The shift cancel pattern may include a first atomic layer 241a and a second atomic layer 242a alternately repeatedly stacked.

The first atomic layer 241a may include the Pt atoms and the Pd atoms. Since the Pt atoms may be infiltrated through the sidewalls of the shift cancel pattern 240b, the concentration of Pt atoms in the first atomic layer 241a may be gradually higher from the central region AR1 to the edge region AR2. Moreover, a small amount of the Pd in the first atomic layer 242b may remain in the central region AR2. For example, the concentration of the Pd atoms may be gradually higher from the edge region AR2 to the central region AR1.

According to some embodiments, the second atomic layer 242a may include the Co atoms.

As mentioned above, the first atomic layer 241a may have bonds between the Pt metal atoms and the Pd metal atoms. As it is well known, a lattice constant (interatomic lattice length) of the Pt metal may be larger than a lattice constant of the Pd metal, which may result in strain stress generated at the Pt-Pd bonds. For example, the strain stress may be relatively high in the edge region AR2 of the first atomic layer 241a, where the concentration of the Pt metal atoms is comparatively greater. Further, since the strain stress may act in a direction perpendicular to the surface of the first atomic layer 241a, it may enhance the vertical magnetic anisotropy characteristic of the shift cancel pattern 240b. Accordingly, the shift cancel pattern 240b may obtain the magnetic moment characteristic and the vertical magnetic anisotropy characteristic (indicated by the arrows in FIG. 9) superior to the temporary auxiliary pattern of CoPd.

According to embodiments of the present disclosure, during the ion beam etching process of the temporary magnetic layer including the X metal atoms and the strongly oxidizing Y metal atoms as the free electrons and the magnetic tunnel junction layer, the Y metal atoms dissociated from the temporary shift cancel pattern and redeposited may be converted into metal oxides, thereby preventing the bridge and the shunt defects. Further, the Y metal atoms remaining in the temporary shift cancel layer may be replaced with the Z metal atoms, such as the Pt atoms, which may improve the magnetic properties, thereby enhancing the vertical magnetic anisotropy characteristics of the shift cancel pattern. As a result, the electrical characteristics of the magnetic memory device may be improved.

While the embodiments of the present disclosure have been described in detail with reference to specific embodiments, the present disclosure is not limited to the above embodiments. The embodiments are capable of many modifications within the scope of the present disclosure by those having ordinary skill in the art. Furthermore, the embodiments may be combined to form additional embodiments.

What is claimed is:

1. A method of manufacturing a magnetic memory device, the method comprising:
forming a temporary shift cancel layer including X metal atoms and Y metal atoms as free atoms;
forming a magnetic tunnel junction layer on the temporary shift cancel layer;
etching the magnetic tunnel junction layer and the temporary shift cancel layer to form a magnetic tunnel junction pattern and a temporary shift cancel pattern, respectively;
oxidizing the Y metal atoms, which are redeposited between the magnetic tunnel junction pattern and the temporary shift cancel pattern, to form metal oxide; and
substituting the Y metal atoms of the temporary shift cancel pattern with Z metal atoms to form a shift cancel pattern,
wherein the Y metal atoms have higher oxidizing than the Z metal atoms, and
wherein the Z metal atoms have a higher reduction potential than the Y metal atoms.

2. The method of claim 1,
wherein the X metal atoms comprise at least one of Co metal atoms and Fe metal atoms;
wherein the Y metal atoms comprise at least one of Pd metal atoms and Ni metal atoms, and
wherein the Z metal atoms comprise Pt metal atoms.

3. The method of claim 1, wherein forming the temporary shift cancel layer comprises:
depositing a first atomic layer including the Y metal atoms; and
depositing a second atomic layer including the X metal atoms on the first atomic layer,
wherein depositing the first atomic layer and depositing the second atomic layer are repeated at least once.

4. The method of claim 1, wherein forming the magnetic tunnel junction layer comprises:
forming a first magnetic layer on the temporary shift cancel layer;
forming a tunnel barrier layer on the first magnetic layer; and
forming a second magnetic layer on the tunnel barrier layer.

5. The method of claim 1, wherein forming the magnetic tunnel junction pattern and forming the temporary shift cancel pattern comprise etching the magnetic tunnel junction layer and the shift cancel layer using an ion beam at least once, respectively.

6. The method of claim 1, wherein forming the shift cancel pattern above comprises immersing the temporary shift cancel pattern in a solution containing Z metal atoms.

7. The method of claim 6, wherein the solution containing the Z metal atoms comprises H₂PtCl₆, PtCl₂, PtCl₄, or PtF₄.

8. The method of claim 1, further comprising forming an insulating interlayer between the shift cancel pattern and the magnetic tunnel junction pattern,
wherein the metal oxide is included as a part of the insulating interlayer.

9. A method of manufacturing a magnetic memory device, the method comprising:
forming a switching structure on a semiconductor substrate;
forming a temporary shift cancel layer on top of the switching structure, the temporary shift cancel layer including X metal atoms, which include at least one of Co and Fe, and Y metal atoms, which include at least one of Pd and Ni;
stacking a first magnetic layer, a tunnel barrier layer, and a second magnetic layer on the temporary shift cancel layer to form a magnetic tunnel junction layer; and
etching the magnetic tunnel junction layer and the temporary shift cancel layer using an ion beam at least once to form a temporary shift cancel pattern and a magnetic tunnel junction pattern on the switching structure, respectively;
oxidizing between the magnetic tunnel junction pattern, and a sidewall portion of the magnetic tunnel junction pattern; and
substituting the Y metal atoms with Pt metal atoms through a sidewall of the temporary shift cancel pattern to form a shift cancel pattern.

10. The method of claim 9, wherein forming the temporary shift cancel layer comprises:
depositing a first atomic layer including the Y metal atoms; and
depositing a second atomic layer including the X metal atoms on the first atomic layer,
wherein depositing the first atomic layer and depositing the second atomic layer are repeated at least once.

11. The method of claim 9,
wherein the Y metal atoms of the temporary shift cancel layer are redeposited between the magnetic tunnel junction patterns and on a sidewall of the magnetic tunnel junction patterns when the magnetic tunnel junction layer and the temporary shift cancel layer are etched using the ion beam, and
wherein, the redeposited Y metal atoms are oxidized to form metal oxide.

12. The method of claim 9, wherein forming the shift cancel pattern comprises immersing the temporary shift cancel pattern in a solution containing Pt metal atoms.

13. The method of claim 12, wherein the solution containing Pt metal atoms comprises H₂PtCl₆, PtCl₂, PtCl₄, or PtF₄.
